(19) United States
(12) Patent Application Publication
(10) Pub. No.: US 2018/0277197 A1
(43) Pub. Date: Sep. 27, 2018

(54) SRAM CELL

(71) Applicant: Commissariat à l'Énergie Atomique et aux Énergies Alternatives, Paris (FR)

(72) Inventors: Jean-Philippe Noel, Montbonnot Saint Martin (FR); Kaya Can Akyel, Grenoble (FR); Bastien Giraud, Voreppe (FR)

(73) Assignee: Commissariat à l'Énergie Atomique et aux Énergies Alternatives, Paris (FR)

(21) Appl. No.: 15/937,454

(22) Filed: Mar. 27, 2018

(30) Foreign Application Priority Data
Mar. 27, 2017 (FR) 1752529

(51) Int. Cl. G11C 11/412; H01L 27/11

(52) U.S. Cl. CPC G11C 11/412; H01L 27/1104

(57) ABSTRACT

A SRAM cell, including, in a stack of layers, transistors including at least first and second access transistors connected to a word line, the first access transistor coupling a first bit line and a first storage node and the second access transistor coupling a second bit line and a second storage node, and a flip-flop including a first conduction transistor coupling the first storage node to a source of a first reference potential and having its gate coupled to the second storage node and a second conduction transistor coupling the second storage node to the source of the first reference potential and having its gate coupled to the first storage node.

### BACKGROUND

The present disclosure concerns memories, and particularly static random access memories, also called SRAM.

### DISCUSSION OF THE RELATED ART

FIG. 1 shows a conventional SRAM cell comprising two inverters 10, 11 connected according to a so-called flip-flop configuration, and two access transistors 12, 13 connected to bit lines 15 and 16 and controlled by a word line 17.

The characteristics desired for a memory cell are:

a good static noise margin, SNM;

a sufficient write margin, WM;

a good retention noise margin, RNM;

a conduction current, through access transistors 12, 13, which is as high as possible to give the cell a high operating speed;

as small a cell size as possible to enable to form a memory with a significant cell integration density;

as low a retention current as possible to minimize the consumed static power.

Since these criteria cannot all be satisfied, memory designers are led to making compromises therebetween. In particular, SRAM cells are generally optimized at the time of their design according to the targeted application.

It is known to provide assistance circuits to achieve the characteristics desired for a memory cell. However, this results in the addition of additional circuits in the memory, which may cause a non-negligible additional cost in terms of surface area and of electric power consumption.

The problem of finding a new SRAM cell structure having on the one hand a good retention noise margin, in read and write mode, while keeping a small bulk and a sufficient speed, is posed.

### SUMMARY

An object of an embodiment is to overcome all or part of the disadvantages of previously-described SRAMs.

Another object of an embodiment is for the provided SRAM to comprise assistance circuits with substantially no additional cost in terms of surface area.

Another object of an embodiment is for the SRAM cell to have an increased retention noise margin.

Another object of an embodiment is for the SRAM cell to have an increased static noise margin or read stability.

Another object of an embodiment is for the SRAM cell to have an increased write stability.

Another object of an embodiment is for the SRAM cell to have a low bulk.

Another object of an embodiment is for the minimum power supply voltage of the SRAM cell to be decreased.

Thus, an embodiment provides a SRAM cell, comprising, in a stack of layers, transistors including at least first and second access transistors connected to a word line, the first access transistor coupling a first bit line and a first storage node and the second access transistor coupling a second bit line and a second storage node, and a flip-flop comprising a first conduction transistor coupling the first storage node to a source of a first reference potential and having its gate coupled to the second storage node and a second conduction transistor coupling the second storage node to the source of the first reference potential and having its gate coupled to the first storage node, the transistors being distributed into a first plurality of transistors located at a first level of the stack and a second plurality of transistors located at at least a second level of the stack, the memory cell comprising an electrically-conductive portion of the second level connected to an element selected from among the first storage node, the second storage node, the first bit line, and the second bit line and located opposite a channel area of a transistor of the first plurality of transistors and separated from said channel area via an insulating area provided or electrically connected to a semiconductor portion containing said channel area to allow a coupling between the electrically-conductive portion and said channel area.

According to an embodiment, the electrically-conductive portion is connected to one of the first storage node or of the second storage node.

According to an embodiment, the flip-flop further comprises a third conduction transistor coupling the first storage node to a source of a second reference potential and having its gate coupled to the second storage node and a fourth conduction transistor coupling the second storage node to the source of the second reference potential and having its gate coupled to the first storage node.

According to an embodiment, the first and second access transistors and the first and second conduction transistors are located in the second level. The third and fourth conduction transistors are located in the first level. The channel area of the third conduction transistor is coupled to the second storage node and the channel area of the fourth conduction transistor is coupled to the first storage node.

According to an embodiment, the first and second access transistors are located in the first level. The first and second conduction transistors are located in the second level. The channel area of the first access transistor is coupled to the second storage node and the channel area of the second access transistor is coupled to the first storage node.

According to an embodiment, the cell further comprises a readout circuit comprising first and second readout transistors, the first storage node being connected to the gate of the second readout transistor, the first readout transistor coupling the second readout transistor to a first read bit line, the gate of the second readout transistor being connected to a second read bit line. The first and second readout transistors are located in the first level. The first and second access transistors and the first and second conduction transistors are located in the second level. The channel area of the first readout transistor is coupled to the first storage node and the channel area of the second readout transistor is coupled to the first storage node.

According to an embodiment, the electrically-conductive portion is connected to one of the first bit line or of the second bit line.

According to an embodiment, the first and second access transistors are located in the second level. The first and second conduction transistors are located in the first level. The channel area of the first conduction transistor is coupled to the second bit line and the channel area of the second conduction transistor is coupled with the first bit line.

According to an embodiment, the third and fourth conduction transistors are located in the second level.

An embodiment also provides a memory comprising cells such as previously defined, having first cells distributed in a first portion of the stack and second cells distributed in a second portion of the stack, the first cells forming at least one column, the memory comprising a first electrically-conductive track extending along the column and forming the first bit line of each first cell and a second electrically-conductive track extending along the column and forming the second bit line of each first cell, the memory further comprising interconnection elements extending through the layers of the stack and coupling each second memory cell to the first and second tracks.

According to an embodiment, the first and second tracks are made of a first material. The interconnection elements are made of a second material having a poorer electric conductivity than the first material.

### BRIEF DESCRIPTION OF THE DRAWINGS

The foregoing and other features and advantages will be discussed in detail in the following non-limiting description of specific embodiments in connection with the accompanying drawings, in which:

FIG. 1, previously described, is an electric diagram of an example of a SRAM cell;

FIG. 2 is a diagram illustrating an embodiment of a SRAM cell over two levels;

FIGS. 3A and 3B are partial simplified cross-section views of embodiments of the SRAM cell of FIG. 2;

FIG. 4 is a general electric diagram of a SRAM cell with six transistors;

FIG. 5 illustrates an embodiment of a SRAM cell with six transistors having its transistors distributed over two levels;

FIGS. 6 and 7 illustrate embodiments of SRAM cells with four transistors, having their transistors distributed over two levels;

FIG. 8 illustrates an embodiment of a SRAM cell with eight transistors having its transistors distributed over two levels;

FIG. 9 illustrates an embodiment of a content-addressable memory cell having its transistors distributed over two levels;

FIG. 10 illustrates an embodiment of a SRAM cell with six transistors having its transistors distributed over two levels;

FIGS. 11 and 12 illustrate embodiments of SRAM cells with four transistors, having their transistors distributed over two levels;

FIG. 13 is a diagram illustrating an embodiment of an electronic circuit formed over a plurality of levels;

FIG. 14 is a diagram of a SRAM formed on a single level;

FIGS. 15 and 16 are diagrams illustrating an embodiment of a SRAM over two levels;

FIG. 17 illustrates an embodiment of a SRAM cell with six transistors having its transistors distributed over two levels;

FIG. 18 illustrates an embodiment of a content-addressable memory cell having its transistors distributed over two levels;

FIG. 19 is a diagram similar to FIG. 15 illustrating another embodiment of a SRAM over two levels; and

FIG. 20 is a partial simplified perspective view of an embodiment of the SRAM cell of FIG. 7.

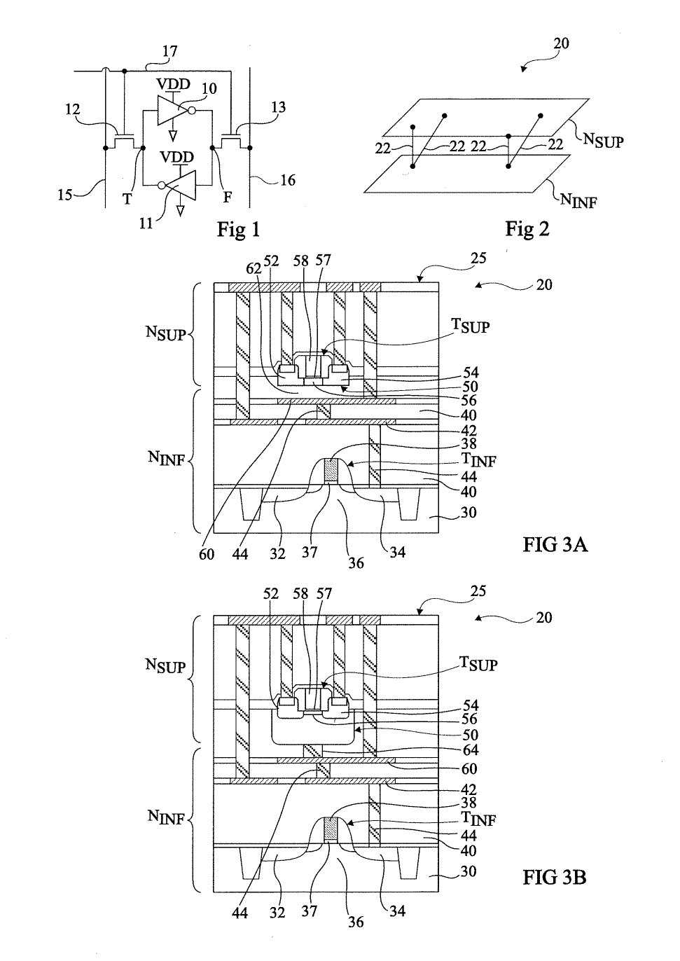

### DETAILED DESCRIPTION

The same elements have been designated with the same reference numerals in the different drawings. For clarity, only those steps and elements which are useful to the understanding of the described embodiments have been shown and are detailed. The terms “approximately”, “substantially”, and “in the order of” are used herein to designate a tolerance of plus or minus 10%, preferably of plus or minus 5%, of the value in question.

FIG. 2 very schematically shows an embodiment of an improved SRAM cell 20 comprising transistors, particularly metal oxide semiconductor field-effect transistors, currently called MOSFETs, formed in a stack of an electronic circuit over two levels of the stack. In particular, the memory cell comprises transistors located in an upper level NSUP, which have a threshold voltage capable of being modulated, the channel of each of the transistors being electrically coupled to a node of the electronic circuit of a lower level NINF via electrically-conductive vias 22. Such a structure provides advantages, particularly in terms of bulk, and the possibility of dynamically modifying the threshold voltage of some of the transistors to improve their electric characteristics such as the stability and/or the power consumption.

FIGS. 3A and 3B are partial simplified cross-section views of embodiments of SRAM cell 20, comprising a stack 25 of layers. For each of these embodiments, the layers of stack 25 are distributed into layers of upper level NINF and layers of upper level NSUP. The layer at the base of the stack is called substrate 30. Substrate 30 may be a solid substrate or a semiconductor-on-insulator or SOI type substrate comprising a first support layer which may be semiconductor and for example made up of Si, covered with an insulating layer, for example, made up of SiO₂, itself covered with a semiconductor layer, for example, made up of Si, and where one or a plurality of active areas are capable of being formed.

A first transistor T_{INF} is formed inside and on top of substrate 30. First transistor T_{INF} comprises a source region 32, a drain region 34, as well as a channel area 36, coupling source region 32 and drain region 34. First transistor T_{INF} may be optionally formed on a fully depleted or partially depleted SOI substrate. Transistor TINF also comprises a gate 38 located on a layer of dielectric material 37 of gate 38.

A succession of insulating layers 40, of electrically-conductive tracks 42 formed between electrically-insulating layers 40 and of electrically-conductive vias 44 through the insulating layers is also provided in lower level N_{INF}.

SRAM cell 20 also comprises at least one second transistor T_{SUP} in a level N_{SUP} of the stack higher than level N_{INF} where first transistor T_{INF} is located. Second transistor T_{SUP} comprises, in a semiconductor portion 50, a source region 52, a drain region 54, as well as a channel structure 56, coupling source region 52 and drain region 54. Second transistor T_{SUP} also comprises a gate 58 resting on a gate dielectric layer 57.

In the embodiment shown in FIG. 3A, second transistor T_{SUP} is formed according to a fully depleted substrate-on-insulator or FDSOI technology. In this embodiment, channel structure 56 is located above an electrically-conductive track, preferably a metal track 60 of the last metallization level of lower level N_{INF} and separated from metal track 60 by an electrically-insulating area 62. Insulating area 62 is formed to allow a coupling between metal track 60 and the channel of second transistor T_{SUP} located thereabove. Preferably, the thickness of insulating area 62 is in particular selected to be much smaller than the thicknesses of the layers of dielectric materials between levels in prior art electronic circuits, which, in such electronic circuits, are provided to enable to insulate from one another different stacked levels of components or of interconnection lines.

Conductive track 60 thus enables to control the channel potential of transistor T_{SUP} of upper level N_{SUP}. Preferably, to obtain a better control of the channel potential of second transistor T_{SUP}, the entire channel semiconductor area 56 of second transistor T_{SUP} is arranged opposite the upper surface or the top of conductive track 60. Channel area 56 of second transistor T_{SUP} may be formed in a semiconductor layer of small thickness, to allow a static control at the level of the inversion channel. Small thickness means that channel area 56 of second transistor T_{SUP} may be formed in a semiconductor portion 50 having a thickness for example in the range from 1 nm to 100 nm or, for example, from 5 nm to 20 nm. The thickness selected for semiconductor portion 50 having channel 56 formed therein is provided, in particular, according to the doping level of this layer to allow a fully depleted behavior.

The channel areas of transistors T_{SUP} and T_{INF} may be formed, for example, in Si or in another semiconductor material, for example, such as Ge. Insulating area 62, separating conductive track 60 from semiconductor portion 50 where channel 56 of transistor T_{SUP} is formed, is provided to allow a significant coupling of conductive track 60 with channel 56. Significant coupling means a coupling enabling to vary the threshold voltage of upper level transistor T_{SUP} by at least 50 mV, for a variation of the applied voltage to lower level conductive track 60 between 0 and Vdd or −Vdd and +Vdd according to the application, Vdd being the power supply voltage of the SRAM. Voltage Vdd may for example be in the order of 1 V or of 0.5 V. A model such as that described in Lim and Fossum's article: IEEE Transactions on electron devices, vol. ED-30, n° 10 Oct. 1983, may be used to size insulating area 62 to obtain a desired threshold voltage variation ΔVₜₕ when varying by ΔV the bias potential of conductive track 60. A model according to the following relation (1) may be used in particular in the case where second transistor T_{SUP} is formed on a fully depleted layer:

$$Δ {V}_{th} = \frac{\frac{{ɛ}_{SC}}{{T}_{SC}} \cdot \frac{{ɛ}_{ILD}}{{T}_{ILD}}}{\frac{{ɛ}_{OX}}{{T}_{OX}} \cdot ( \frac{{ɛ}_{SC}}{{T}_{SC}} + \frac{{ɛ}_{ILD}}{{T}_{ILD}} )} \cdot Δ V \qquad ( 1 )$$

where:

ΔVₜₕ is the threshold voltage variation of transistor T_{SUP};

ε_{sc} and T_{sc} respectively are the dielectric permittivity and the thickness of semiconductor portion 50 where channel 56 of transistor T_{SUP} is formed;

εₒₓ and Tₒₓ respectively are the dielectric permittivity and the thickness of gate dielectric 57 of second transistor T_{SUP}; and

ε_{ILD} and T_{ILD} respectively are the dielectric permittivity and the thickness of the dielectric of insulating area 62 separating semiconductor portion 50 of second transistor T_{SUP} from conductive track 60.

The following relation (2) is obtained when the potential of conductive track 60 varies from 0 to Vdd:

$$Δ {V}_{th} = \frac{\frac{{ɛ}_{SC}}{{T}_{SC}} \cdot \frac{{ɛ}_{ILD}}{{T}_{ILD}}}{\frac{{ɛ}_{OX}}{{T}_{OX}} \cdot ( \frac{{ɛ}_{SC}}{{T}_{SC}} + \frac{{ɛ}_{ILD}}{{T}_{ILD}} )} \cdot Vdd \qquad ( 2 )$$

To achieve a significant coupling corresponding to a threshold variation ΔVₜₕ equal to 50 mV, in the case where thickness Tx of channel area 56 is equal to 7 nm, where the latter is made of silicon, where of dielectric area 57 is equal to 1 nm, where the latter is made up of SiO₂, where Vdd is equal 1 V, and where insulating layer 62 is made of SiO₂, insulating area 62 is for example provided with a thickness in the order of 17.5 nm.

In the embodiment shown in FIG. 3B, second transistor T_{SUP} is formed according to a partially depleted substrate-on-insulator or PDSOI technology. In this embodiment, conductive track 60 may be electrically connected to semiconductor portion 50, for example, by an electrically-conductive via 64 outside of source region 52, of drain region 54, and of channel structure 56. Conductive track 60 thus enables to control the channel potential of transistor T_{SUP} of upper level N_{SUP}.

An example of electronic circuit has been described with two transistors in two stacked levels. Memory cell 20 may however comprise a higher number of transistors, for example, a number n (n being an integer such that n>2) of stacked transistors T₁, T₂, . . . , Tₙ, each transistor Tₖ of a given level Nₖ (k being an integer such that 1<k<n) comprising a channel area capable of being coupled to a conductive track of level Nₖ₋₁ lower than the given level Nₖ, the conductive track being located opposite said channel area, at a sufficiently small distance to allow such a coupling.

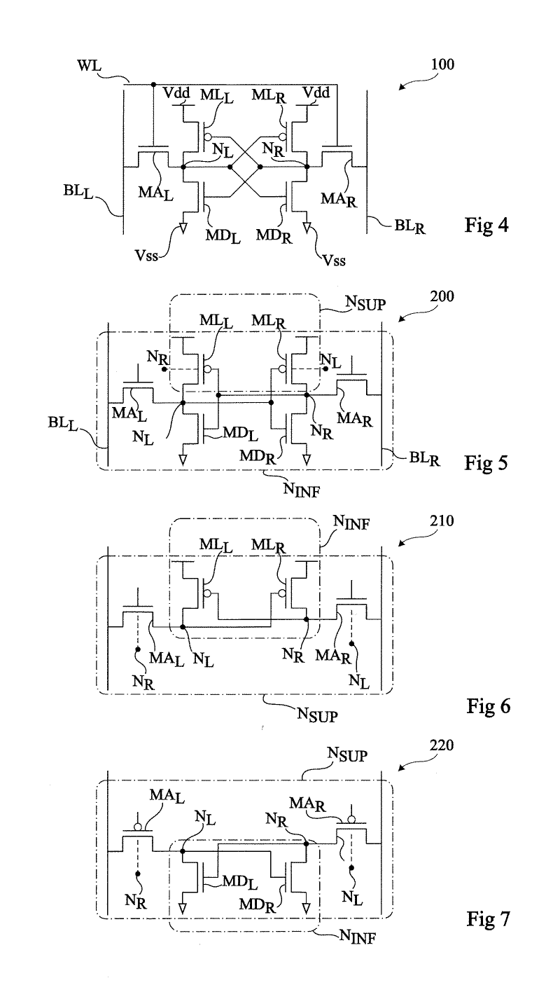

FIG. 4 is an electric diagram of an embodiment of a random access memory cell 100 of 6T type, that is, provided with 6 transistors. Cell 100 comprises a plurality of transistors forming a first inverter and a second inverter, connected according to a flip-flop configuration.

In this example, the flip-flop comprises a first conduction transistor MD_{L} and a second conduction transistor MD_{R}, for example of N-channel MOS type. The gate of second conduction transistor MD_{R} is connected to a first storage node N_{L} of cell 100 and the gate of first conduction transistor MD_{L} is connected to a second storage node N_{R} of cell 100. The sources of conduction transistors MD_{L}, MD_{R}, are interconnected and connected to a source of a low reference potential Vss, for example, the ground. The drain of first conduction transistor MD_{L} is connected to first node N_{L} and the drain of second conduction transistor MD_{R} is connected to second node N_{R}. The flip-flop further comprises a first charge transistor ML_{L} and a second charge transistor ML_{R}, for example, of P-channel MOS type. The sources of charge transistors ML_{L}, ML_{R}, are connected to a source of a high reference potential Vdd and the drain of first charge transistor ML_{L} is connected to first node NL and the drain of second charge transistor ML_{R} is connected to second node NR.

SRAM cell 100 is also provided with a first access transistor MA_{L} and with a second access transistor MA_{R}, for example, N-channel MOS transistors. Access transistors MA_{L} and MA_{R} comprise a gate connected to a word line WL. The source of first access transistor MA_{L} is connected to a first bit line BL_{L} and the source of second access transistor MA_{R} is connected to a second bit line BL_{R}. The drain of first access transistor MA_{L} is connected to first storage node N_{L} and the drain of second access transistor MA_{R} is connected to second storage node N_{R}.

Access transistors MA_{L}, MA_{R} are arranged to enable to access to storage nodes N_{L} and N_{R} during a phase of reading from or writing into cell 100, and to block the access to cell 100 when cell 100 is in a data retention mode.

Conduction transistors MD_{L}, MD_{R} and charge transistors ML_{L}, ML_{R} are provided to hold a charge necessary to establish a given logic level, for example, ‘0’, for example corresponding to a potential equal to potential Vss, or ‘1’, for example corresponding to a potential equal to potential Vdd, on one of nodes N_{L} or N_{R}, according to the logic value stored in cell 100.

FIG. 5 illustrates an embodiment of a SRAM cell 200 with six transistors having its transistors distributed over two levels N_{INF} and N_{SUP} and where a read assistance method is implemented. SRAM cell 200 comprises all the elements of memory cell 100 shown in FIG. 4. N-channel MOS transistors MA_{L}, MA_{R}, MD_{L} and MD_{R} are located in lower level N_{INF} and P-channel MOS transistors ML_{L} and ML_{R} are located in upper level N_{SUP}. In the present embodiment, the channel area of first charge transistor ML_{L} is coupled to second storage node N_{R} and the channel area of second charge transistor ML_{R} is coupled to first storage node N_{L}, which is schematically shown in FIG. 5 by dotted lines.

Due to such a layout, the threshold voltage of first charge transistor ML_{L} depends on the data stored in second storage node N_{R} and the threshold voltage of second charge transistor ML_{R} depends on the data stored in first storage node N_{L}. The present embodiment enables to lower the threshold voltage of the P-channel MOS transistor used to take the inner storage node back to Vdd (and thus store logic value ‘1’).

An operating mode of cell 200 during a read operation will now be described.

Bit lines BL_{L} and BL_{R} are precharged to Vdd before the read operation. Word line WL is then biased to Vdd to access the data stored in storage nodes N_{L}, N_{R} via bit lines BL_{L} and BL_{R}. Access transistors MA_{L} and MA_{R} are then in a conductive state.

In the case where first node NL is at a high logic level, for example, at potential Vdd, and where second node NR is at a low logic level, for example, at 0 V, a conduction current is established between bit lines BLR and ground Vss via second conduction transistor MDR and second access transistor MAR, causing a discharge of bit line BLR to ground. Such a voltage drop on bit line BLR causes a voltage difference between bit lines BLL and BLR and the detection of this difference completes the reading through a sense amplifier. However, the discharge of bit line BLR to ground causes a voltage increase at second storage node NR. Such a voltage increase should not cause the switching of the cell state. Since first charge transistor ML_{L} is made more conductive, this enables to prevent for it to be turned on at the voltage rise of second storage node N_{R}. This improves the static noise margin or read stability of the SRAM cell.

FIG. 6 illustrates an embodiment of a SRAM cell 210 with four transistors, having its transistors distributed over two levels N_{INF} and N_{SUP} and where a read and retention assistance method is implemented. SRAM cell 210 comprises all the elements of memory cell 100 shown in FIG. 4, with the difference that first conduction transistor MDL and second conduction transistor MDR are not present. N-channel MOS transistors MA_{L} and MA_{R} are located in upper level N_{SUP} and P-channel MOS transistors ML_{L} and ML_{R} are located in lower level N_{INF}. In the present embodiment, the channel area of first access transistor MA_{L} is coupled to second storage node NR and the channel area of second access transistor MA_{R} is coupled to first storage node NL.

Due to such a layout, the threshold voltage of first access transistor MA_{L} depends on the data stored in second storage node N_{R} and the threshold voltage of second access transistor MA_{R} depends on the data stored in first storage node N_{L}. The present embodiment enables to increase the threshold voltage of the access transistor connected to the inner node where logic value ‘1’ is stored.

An operating mode of cell 210 during a read operation will now be described. Bit lines BL_{L} and BL_{R} are precharged to 0 V and access transistors MA_{L} and MA_{R} are taken to a conductive state. In the case where first node N_{L} is at Vdd and where second node N_{R} is at 0 V, the threshold voltage of first access transistor MA_{L} is increased, which makes it less conductive. The potential at node NL is then better held in a high logic state, which thus increases the stability of the read operation.

An operating mode of cell 210 will now be described during a retention operation, that is, in the absence of a read or write operation in the cell. Bit lines BL_{L} and BL_{R} are precharged to 0 V and access transistors MA_{L} and MA_{R} then are in an off state. In the case where first node N_{L} is at Vdd and where first node N_{R} is at 0 V, the threshold voltage of first access transistor MA_{L} is increased, which enables to decrease the leakage currents flowing through first access transistor MA_{L}. The retention time of memory cell 210 is then increased.

FIG. 7 illustrates an embodiment of a SRAM cell 220 with four transistors having its transistors distributed over two levels N_{INF} and N_{SUP} and where a retention and read assistance method is implemented. SRAM cell 220 comprises all the elements of memory cell 100 shown in FIG. 4, with the difference that first charge transistors ML_{L} and second charge transistor ML_{R} are not present and that access transistors MA_{L} and MA_{R} are P-channel MOS transistors. P-channel MOS transistors MA_{L} and MA_{R} are located in upper level N_{SUP} and N-channel MOS transistors MD_{L} and MD_{R} are located in lower level N_{INF}. In the present embodiment, the channel area of first access transistor MA_{L} is coupled to second storage node NR and the channel area of second access transistor MA_{R} is coupled to first storage node NL.

Due to such a layout, the threshold voltage of first access transistor MA_{L} depends on the data stored in second storage node N_{R} and the threshold voltage of second access transistor MA_{R} depends on the data stored in first storage node N_{L}. The present embodiment enables to increase the threshold voltage of the access transistor connected to the inner node having logic value ‘0’ stored therein.

An operating mode of cell 220 during a read operation will now be described. Bit lines BL_{L} and BL_{R} are precharged to Vdd and access transistors MA_{L} and MA_{R} are taken to a conductive state. In the case where first node N_{L} is at Vdd and where second node N_{R} is at 0 V, the threshold voltage of second P-type access transistor MA_{R} is increased, which makes it less conductive. The stability of the read operation is thus improved since node NR is better maintained around 0 V since it receives less current originating from bit line BLR.

An operating mode of cell 220 will now be described during a retention operation, that is, in the absence of a read or write operation in the cell. Bit lines BL_{L} and BL_{R} are precharged to Vdd and access transistors MA_{L} and MA_{R} then are in an off state. In the case where first node NL is at Vdd, and where second node NR is at 0 V, the threshold voltage of second access transistor MAR is increased, which enables to decrease the leakage currents flowing through second access transistor MAR. The retention time of memory cell 220 is then increased.

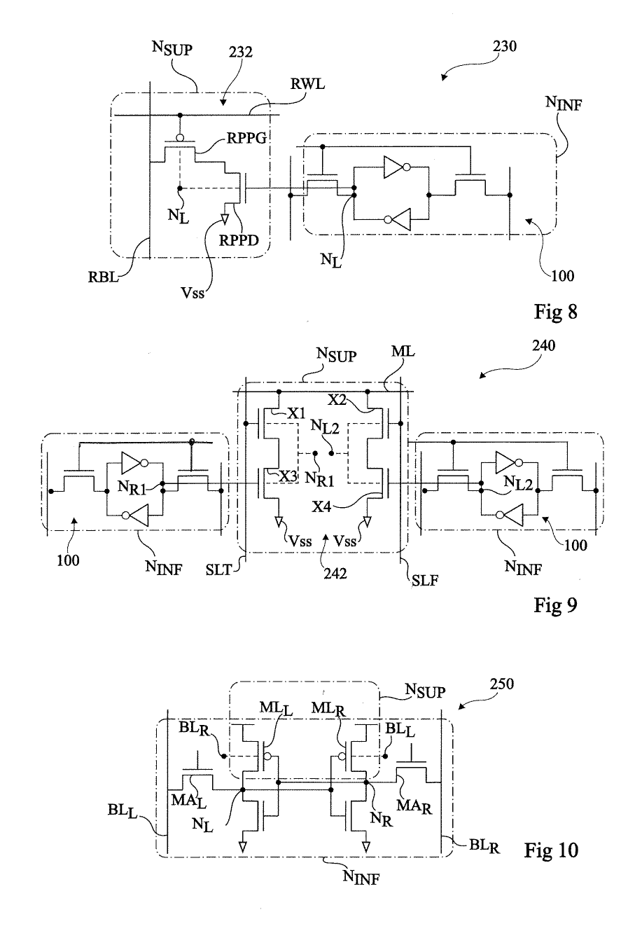

FIG. 8 illustrates an embodiment of a SRAM cell 230 with eight transistors having its transistors distributed over two levels and where a read assistance method is implemented.

8T SRAM cell 230 comprises memory cell 100 shown in FIG. 4 and further comprises a readout circuit 232 comprising two MOS transistors RPPG and RPPD, which both have an N channel. As a variation, MOS transistors RPPG and RPPD may both have a P channel. Storage node NL of SRAM cell 100 is connected to the gate of transistor RPPD. The source of transistor RPPD is connected to ground Vss and the drain of transistor RPPD is connected to the source of transistor RPPG. The drain of transistor RPPG is connected to a read bit line RBL and the gate of transistor RPPG is connected to a read word line RWL. All the MOS transistors of SRAM cell 100 are located in lower level NINF and MOS transistors RPPG and RPPD of readout circuit 232 are located in upper level NSUP. In the present embodiment, the channel area of MOS transistor RPPG and the channel area of transistor RPPD are coupled to first storage node NL. The present embodiment enables to decrease the threshold voltage of transistors RPPG and RPPD when logic value ‘1’ is stored in storage node NL.

An operating mode of cell 230 will now be described during a read operation. Bit lines BL_{L} and BL_{R} are precharged to Vdd and access transistors MA_{L} and MA_{R} are taken to a conductive state. In the case where first storage node NL is at Vdd and where second storage node NR is at 0 V, transistor RPPD is activated and a path is created between read bit line RBL and ground Vss. The reading is completed by the detection (or not) of the voltage drop on read bit line RBL. Transistors RPPG and RPPD being more conductive, this allows an accelerated discharge of read bit line RBL in the case where storage node NL stores logic value ‘1’. The duration of a read operation can thus be decreased. For a circuit containing such a memory and having an operating frequency which may be limited by the duration of an operation of reading from the memory, this enables to increase the circuit operating frequency.

FIG. 9 illustrates an embodiment of a SRAM cell 240 of a content-addressable memory having its transistors distributed over two levels and where a read assistance method is implemented.

8T SRAM cell 240 comprises first and second memory cells 100 such as shown in FIG. 4 and further comprises a logic XOR gate 242. Logic gate 242 comprises two N-channel MOS transistors X1 and X3. Second storage node NR1 of the first SRAM cell is connected to the gate of transistor X3. The source of transistor X3 is connected to ground Vss and the drain of transistor X3 is connected to the source of transistor X1. The gate of transistor X1 is connected to a read bit line SLT and the drain of transistor X1 is connected to a read word line ML. Logic gate 242 further comprises two N-channel MOS transistors X2 and X4. First storage node NL2 of the second SRAM cell is connected to the gate of transistor X4. The source of transistor X4 is connected to ground Vss and the drain of transistor X4 is connected to the source of transistor X2. The gate of transistor X2 is connected to a read bit line SLF and the drain of transistor X2 is connected to read word line ML. All the MOS transistors of the first and second SRAM cells 100 are located in lower level NINF and the MOS transistors of logic gate 242 are located in upper level NSUP.

The values stored in the first and second 6T memory cells 100 determine the value stored in memory cell 240. As an example, if logic value ‘0’ is stored at second storage node N_{R1} of the first memory cell and if value ‘1’ is stored at first storage node N_{L2} of the second memory cell, it is then considered that logic value ‘0’ is stored in memory cell 240. Further, if logic value ‘1’ is stored at second storage node N_{R1} of the first memory cell and if value ‘0’ is stored at first storage node N_{L2} of the second memory cell, it is then considered that logic value ‘1’ is stored in memory cell 240.

XOR gate 242 enables to compare the desired value with the value stored in memory cell 240. The desired value is transmitted to memory cell 240 over read bit line SLT and its complement is transmitted over bit line SLF. A read operation where the desired data correspond to the value stored in memory cell 240 is called a match and a read operation where the desired data do not correspond to the data stored in memory cell 240 is called a miss.

An operating mode of cell 240 during a read operation will now be described. Read word line ML is precharged to Vdd. If a miss occurs, read word line ML is discharged via at least one of two branches of XOR gate 242. The discharge time defines the speed of the read operation. The present embodiment enables to decrease the threshold voltage of transistors X1 and X2 in the case of a miss, which enables to decrease the duration of the read operation.

In the previously-described embodiments where the static noise margin of the memory cells is improved, the memory cell power supply voltage can be decreased.

FIG. 10 illustrates an embodiment of a SRAM cell 250 with six transistors, having its transistors distributed over two levels and where a write assistance method is implemented. SRAM cell 250 comprises all the elements of memory cell 200 shown in FIG. 5, with the difference that the channel area of first charge transistor MLL is coupled to second bit line BLR and the channel area of the second charge transistor MLR is coupled to first bit line BLL.

Due to such a layout, the threshold voltage of first charge transistor MLL depends on the data present on second bit line BLR and the threshold voltage of second charge transistor MLR depends on the data present on first bit line BLL. The present embodiment enables to increase the threshold voltage of the charge transistor connected to the bit line having logic value ‘0’ present thereon and to decrease the threshold voltage of the charge transistor connected to the bit line having logic value ‘1’ present thereon.

An operating mode of cell 250 will now be described during a write operation. Assume that logic value ‘1’ is stored in SRAM cell 250. This means that logic value ‘1’ is stored in first storage node NL and that logic value ‘0’ is stored in second storage node NR. A write operation comprises switching the state of first storage node NL from ‘1’ to ‘0’ and switching the state of second storage node NR from ‘0’ to ‘1’. For this purpose, first bit line BLL is precharged to Vss and second bit line BLR is precharged to Vdd. Access transistors MAL and MAR are then taken to the conductive state. A conduction path is created between first storage node NL and first bit line BL_{L} via first access transistor MA_{L} and a conduction path is created between second storage node N_{R} and second bit line BL_{R} via second access transistor MA_{R}. First storage node N_{L} discharges towards first bit line BL_{L} and second bit line BL_{R} discharges towards second storage node N_{R}. The threshold voltage of second charge transistor ML_{R} being decreased and the threshold voltage of first charge transistor ML_{L} being increased, this eases the turning on of first charge transistor ML_{L} during the voltage rise of second storage node N_{R} and the switching to the on state of second charge transistor ML_{R} during the voltage decrease of first storage node N_{L}. The write stability of SRAM cell 250 is thus increased.

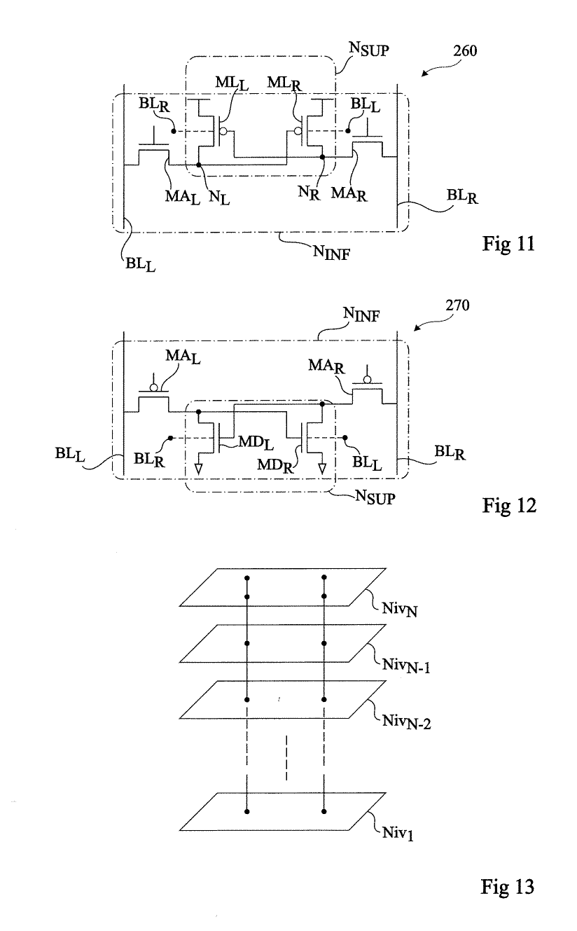

FIG. 11 illustrates an embodiment of a SRAM cell 260 with four transistors having its transistors distributed over two levels and where a write assistance method is implemented. SRAM cell 260 comprises all the elements of memory cell 250 shown in FIG. 10, with the difference that conduction transistors MD_{L} and MD_{R} are not present. In the present embodiment, the channel area of first charge transistor MLL is coupled to second bit line BLR and the channel area of second charge transistor MLR is coupled to first bit line BLL. The operating mode of cell 260 is the same as what has been previously described for memory cell 250. The write stability of SRAM cell 260 is increased.

FIG. 12 illustrates an embodiment of a SRAM cell 270 with four transistors having its transistors distributed over two levels and where a write assistance method is implemented. SRAM cell 270 comprises all the elements of memory cell 250 shown in FIG. 10, with the difference that charge transistors ML_{L} and ML_{R} are not present, that access transistors MA_{L} and MA_{R} are P-channel MOS transistors, that P-channel MOS transistors MA_{L} and MA_{R} are located in lower level N_{INF}, and that N-channel MOS transistors MD_{L} and MD_{R} are located in lower level N_{SUP}. In the present embodiment, the channel area of first conduction transistor MDL is coupled to second bit line BLR and the channel area of second conduction transistor MDR is coupled to first bit line BLL.

Due to such a layout, the threshold voltage of first conduction transistor MDL depends on the data present on second bit line BLR and the threshold voltage of second conduction transistor MDR depends on the data present on first bit line BLL. The present embodiment enables to increase the threshold voltage of the conduction transistor connected to the bit line having logic value ‘1’ present thereon and to decrease the threshold voltage of the conduction transistor connected to the bit line having logic value ‘0’ present thereon.

An operating mode of cell 270 during a write operation will now be described. Assume that logic value ‘1’ is initially stored in SRAM cell 270. This means that logic value ‘1’ is stored in first storage node NL and that logic value ‘0’ is stored in second storage node NR. For a write operation, first bit line BL_{L} is precharged to Vss and second bit line BL_{R} is precharged to Vdd and access transistors MA_{L} and MA_{R} are taken to the conductive state. The threshold voltage of second conduction transistor MD_{R} being decreased and the threshold voltage of first conduction transistor MD_{L} being increased, this eases the switching to the on state of first conduction transistor MD_{L} during the voltage rise of second storage node N_{R} and the turning-on of second conduction transistor MD_{R} during the voltage decrease of first storage node N_{L}. The write stability of SRAM cell 270 is thus increased.

In the embodiments previously described in relation with FIGS. 10 and 12, the duration of a write operation can thus be decreased. For a circuit containing such a memory and having an operating frequency limited by the duration of an operation of writing into the memory, this enables to increase the operating frequency of the circuit.

FIG. 13 partially and schematically shows an embodiment of a SRAM comprising a plurality of memory cells. In the present embodiment, the memory cells of the memory are formed in different levels Niv₁ to Niv_{N} of a stack of layers, where N is an integer, for example, in the range from 2 to 128, level Niv₁ being the base level of the stack and level Niv_{N} being the top level of the stack. Each level may comprise MOS transistors and metal tracks of at least one metallization level. The electrically-conductive material forming the metal tracks of the last metallization level may be different from one level of the stack to another. The electrically-insulating material forming the insulating layers having the conductive tracks formed thereon may be different from one level of the stack to another. According to an embodiment, for level Niv_{N}, the metal tracks of the last metallization level are made of copper and for the other levels Niv₁ to Niv_{N-1}, the metal tracks of the last metallization level are made of tungsten. According to an embodiment, for level Niv_{N}, the electrically-insulating material forming the insulating layers is a so-called low-k material, and for the other levels Niv₁ to Niv_{N-1}, the electrically-insulating material forming the insulating layers is SiO₂. A low-k material is a material having a dielectric constant smaller than 3.9. It is generally not possible to form the metal tracks of a level Niv₁ to Niv_{N-1} with copper to avoid risks of contamination during the forming of the conductive tracks of a higher level.

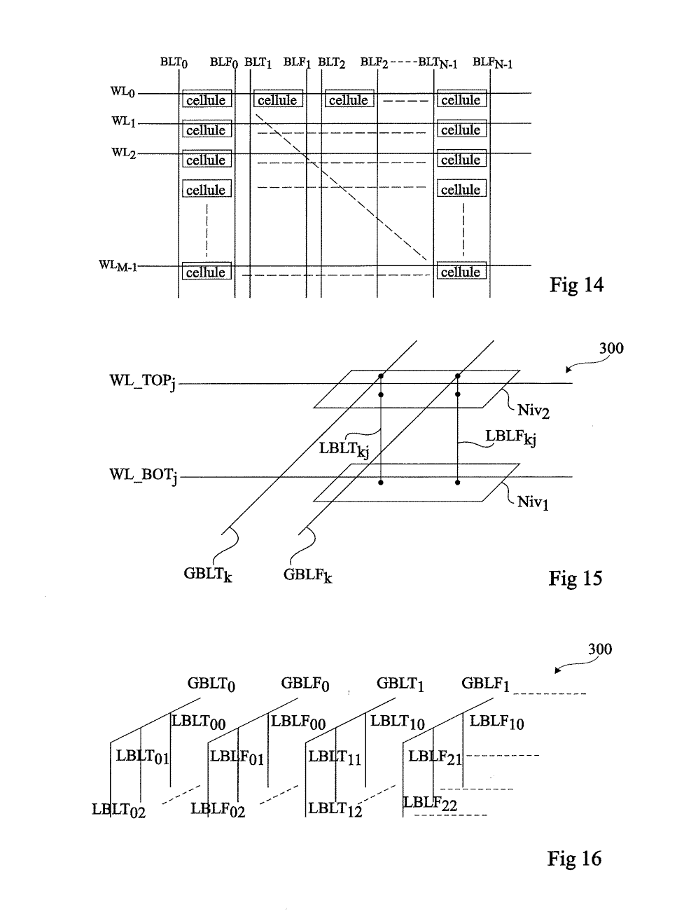

FIG. 14 shows an electric diagram of an example of a SRAM where the SRAM cells are arranged in M rows and in P columns, M and P being integers. The memory comprises, for each row, a word line WLj, j being an integer in the range from 0 to M-1, which is connected to all the memory cells in the row. The memory comprises, for each column, two bit lines BL_{Lk} and BL_{Rk}, k being an integer in the range from 0 to P-1, which are connected to all the memory cells in the column.

According to an embodiment, it is provided to form the memory cells of each memory column in different levels of the stack forming the memory.

FIGS. 15 and 16 show an embodiment of a memory 300 over two levels Niv1 and Niv2 of a stack, having its equivalent electric diagram corresponding to the diagram shown in FIG. 14. In FIG. 15, only two memory cells of the memory have been very schematically shown and FIG. 16 only shows the bit lines of the memory.

In the present embodiment, the memory cells of memory 300 are distributed in levels Niv1 and Niv2. The memory cells of upper level Niv2 are arranged in M/2 rows and P columns. For each column of rank k, k being an integer in the range from 0 to P-1, two bit lines GBLTₖ and GBLFₖ, formed by conductive tracks of upper level Niv₂, are connected to the memory cells of upper level Niv₂ belonging to the considered column. The memory cells of lower level Niv₁ also belonging to the considered column are connected to bit lines GBLTₖ and GBLFₖ by interconnects LBLT_{k,j} and LBLF_{k,j} which connect the memory cells of lower level Niv₁ to metal tracks of upper level Niv₂.

For each row of rank j, where j is an integer in the range from 0 to M/2-1, a word line WL_TOP_{J}, formed by a conductive track of upper level Niv2, is connected to the memory cells of upper level Niv2 belonging to the considered row and a word line WL_BOT_{J}, formed by a conductive track of lower level Niv1, is connected to the memory cells of lower level Niv1 belonging to the considered row.

Level Niv₁ (respectively Niv₂) may itself be divided into a lower sub-level N_{INF} and an upper sub-level N_{SUP}. The transistors of a memory cell of level Niv₁ (respectively Niv₂) can then be distributed over the two sub-levels N_{INF} and N_{SUP} according to one of the structures previously described in relation with FIGS. 5 to 12.

Although, in the embodiment of memory 300 shown in FIGS. 15 and 16, the memory cells are distributed over two levels Niv₁ and Niv₂, it should be clear that the memory cells may be distributed over more than two levels.

The longest metal tracks of memory 300 which correspond to word lines GBLTₖ and GBLFₖ are advantageously formed in upper level Niv2 and can thus be made of a material which is a good electric conductor. As an example, bit lines GBLTₖ and GBLFₖ are made of copper and interconnects LBLT_{k,j} and LBLF_{k,j} are made of tungsten. With such an organization, the access to the memory cells of lower level NINF is not impacted by the use of tungsten in the interconnects and of silicon dioxide SiO₂ for the dielectric of the lower levels.

A significant advantage of the architecture formed over at least two levels, in addition to density gains, is that it enables to significantly decrease the lengths of the conductive tracks forming the bit lines and the word lines. In particular, the length of bit lines GBLTₖ and GBLFₖ is decreased with respect to a memory formed in a single level. The speed of an operation of writing into memory 300 shown in FIGS. 14 and 15 can thus be increased.

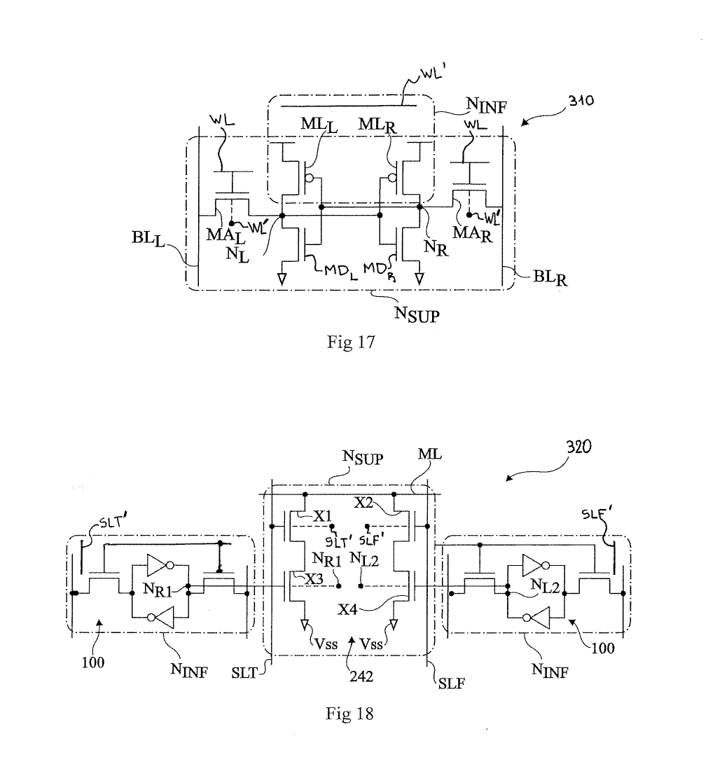

FIG. 17 illustrates an embodiment of a SRAM cell 310 with six transistors having its transistors distributed on two levels N_{INF} and N_{SUP} and where a read assistance method is implemented. SRAM cell 310 comprises all the elements of memory cell 100 shown in FIG. 4. N-channel MOS transistors MA_{L}, MA_{R}, MD_{L}, and MD_{R} are located in upper level N_{SUP} and P-channel MOS transistors ML_{L} and ML_{R} are located in upper level N_{INF}. In the present embodiment, an additional word line WL′ is provided in lower level NINF and receives the same voltage as that applied on word line WL. The channel areas of the first and second access transistors MAL and MAR are coupled to additional word line WL′, which is schematically shown in FIG. 17 by dotted lines.

The present embodiment enables to increase the threshold voltage of access transistors MAL and MAR when word line WL′ is at ‘0’ and to decrease the threshold voltage of access transistors MAL and MAR when word line WL′ is at ‘1’.

FIG. 18 illustrates an embodiment of a SRAM cell 320 of a content-addressable memory having its transistors distributed over two levels N_{INF} and N_{SUP} and where a read assistance method is implemented. SRAM cell 320 comprises all the elements of memory cell 240 shown in FIG. 9, with the difference that an additional read bit line SLY is provided in lower level NINF and receives the same voltage as that applied to read bit line SLT, that an additional read bit line SLF′ is provided in lower level NINF and receives the same voltage as that applied to read bit line SLF, that the channel area of transistor X1 is coupled to read bit line SLY and that the channel area of transistor X2 is coupled or connected to read bit line SLF′.

The channel area of transistor X3 may be coupled or connected as shown in FIG. 9 or may as a variation be coupled to read bit line SLY. The channel area of transistor X4 may be coupled as shown in FIG. 9 or may as a variation be coupled to read bit line SLF′.

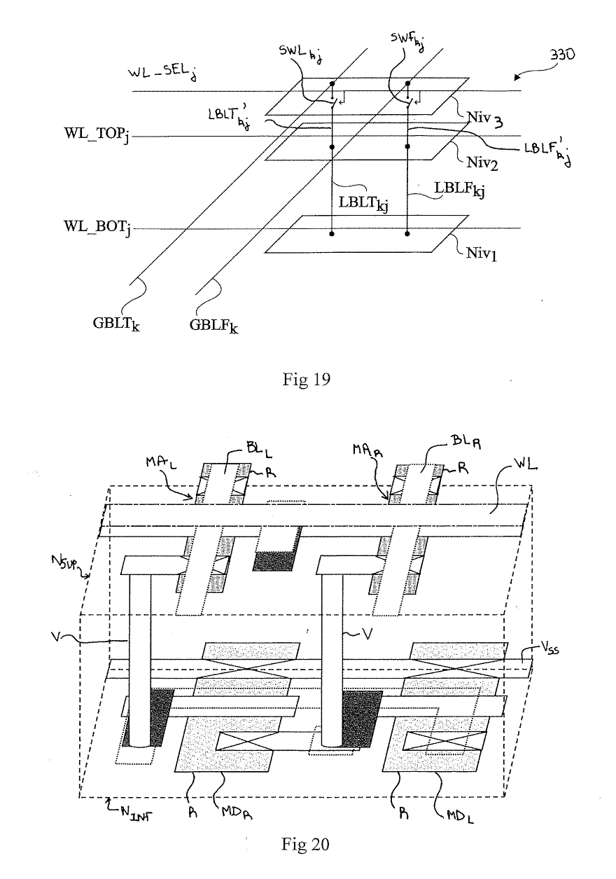

FIG. 19 is a diagram similar to FIG. 15 illustrating another embodiment of a SRAM 330 over two levels. Memory 330 comprises all the memory elements 300 shown in FIGS. 15 and 16 and further comprises an additional level Niv3 having the two bit lines GBLTₖ and GBLFₖ provided therein, a switch SWTkj coupled to bit line GBLTₖ, and a switch SWFkj coupled to bit line GBLFₖ, the memory cells of lower level Niv₂ also belonging to the considered column being respectively connected to switches SWTkj and SWTkj by interconnects LBLT′_{kJ} and LBLF′ₖⱼ. The memory cells of lower levels Niv₁ and Niv2 belonging to the considered column are thus connected to bit lines GBLTₖ and GBLFₖ by interconnects LBLT_{k,j}, LBLFₖⱼ, LBLT′ₖⱼ, LBLF′ₖⱼ which couple the memory cells of lower levels Niv₁ and Niv2 to switches SWTkj and SWFkj of upper level Niv₃. Switches SWTkj and SWFkj are controlled by a selection line WL_SELj. This enables to isolate the cells of bit lines GBLTₖ and GBLFₖ during read and/or write operations.

FIG. 20 is a partial simplified perspective view of an embodiment of the SRAM cell of FIG. 7 over two levels NINF and NSUP. However, in FIG. 20, the couplings of the channel areas of transistors MAL and MAR are not shown. For each level NINF and NSUP, regions R correspond to active semiconductor regions, the tracks in full lines correspond to conductive tracks directly formed on the active areas, the tracks in dotted lines correspond to conductive tracks of a first metallization level, and the track in stripe-dot lines corresponds to a conductive track of a second metallization level. Elements V are conductive vias connecting elements of level NINF to elements of level NSUP.

1. A SRAM, comprising SRAM cells arranged in rows and in columns, electrically-conductive tracks extending along the rows and the columns including word lines, first bit lines, and second bit lines and a circuit for providing signals of variable amplitudes on the conductive tracks, each memory cell comprising in a stack of layers transistors including at least first and second access transistors connected to one of the word lines, the first access transistor coupling one of the first bit lines and a first storage node and the second access transistor coupling one of the second bit lines and a second storage node, and a flip-flop comprising a first conduction transistor coupling the first storage node to a source of a first reference potential and having its gate coupled to the second storage node and a second conduction transistor coupling the second storage node to the source of the first reference potential and having its gate coupled to the first storage node, the transistors being distributed into a first plurality of transistors located at a first level of the stack and a second plurality of transistors located at at least a second level of the stack, the memory cell comprising an electrically-conductive portion of the second level connected to an inner node of the memory cell or to one of the conductive tracks and located opposite a channel area of a transistor of the first plurality of transistors and separated from said channel area via an insulating area provided or electrically-connected to a semiconductor portion containing said channel area to allow a coupling between the electrically-conductive portion and said channel area.

2. The memory of claim 1, wherein, for each memory cell, the electrically-conductive portion is connected to an element selected from among the first storage node, the second storage node, the first bit line, the second bit line, and one of the conductive tracks that is controlled like the word line.

3. The memory of claim 2, wherein, for each memory cell, the electrically-conductive portion is connected to one of the first storage node or of the second storage node.

4. The memory of claim 2, wherein, for each memory cell, the flip-flop further comprises a third conduction transistor coupling the first storage node to a source of a second reference potential and having its gate coupled to the second storage node and a fourth conduction transistor coupling the second storage node to the source of the second reference potential and having its gate coupled to the first storage node.

5. The memory of claim 4, wherein, for each memory cell, the first and second access transistors and the first and second conduction transistors are located in the second level, wherein the third and fourth conduction transistors are located in the first level, wherein the channel area of the third conduction transistor is coupled to the second storage node, and wherein the channel area of the fourth conduction transistor is coupled to the first storage node.

6. The memory of claim 4, wherein, for each memory cell, the first and second access transistors and the first and second conduction transistors are located in the first level, wherein the third and fourth conduction transistors are located in the second level, wherein the channel area of the first access transistor and/or the channel area of the second access transistor is coupled to said conductive track controlled like the word line.

7. The memory of claim 2, wherein, for each memory cell, the first and second access transistors are located in the first level, wherein the first and second conduction transistors are located in the second level, wherein the channel area of the first access transistor is coupled to the second storage node, and wherein the channel area of the second access transistor is coupled to the first storage node.

8. The memory of any of claims 1, further comprising, for at least one of the memory cells, a readout circuit comprising first and second readout transistors, the first storage node of said cell being connected to the gate of the second readout transistor, the first readout transistor coupling the second readout transistor to a first read bit line, the gate of the second readout transistor being connected to a second read bit line, wherein the first and second readout transistors are located in the first level, and wherein the first and second access transistors and the first and second conduction transistors of said cell are located in the second level.

9. The memory of claim 8, wherein the channel area of the first readout transistor is coupled to the first storage node and wherein the channel area of the second readout transistor is coupled to the first storage node.

10. The memory of claim 8, wherein the channel area of the first readout transistor is coupled to one of the conductive tracks that is controlled like the second read bit line.

11. The memory of claim 2, wherein, for each memory cell, the electrically-conductive portion is connected to one of the first bit line or of the second bit line.

12. The memory of claim 2, wherein, for each memory cell, the first and second access transistors are located in the second level wherein the first and second conduction transistors are located in the first level, wherein the channel area of the first conduction transistor is coupled to the second bit line, and wherein the channel area of the second conduction transistor is coupled to the first bit line.

13. The memory of claim 12, wherein, for each memory cell, the third and fourth conduction transistors are located in the second level.

14. The memory of claim 1, wherein the memory cells comprise first cells distributed in a first portion of the stack and second cells distributed in a second portion of the stack, the first cells forming at least one column, the memory comprising a first electrically-conductive track extending along the column and forming the first bit line of each first cell and a second electrically-conductive track extending along the column and forming the second bit line of each first cell, the memory further comprising interconnection elements extending through the layers of the stack and coupling each second memory cell to the first and second tracks.

15. The memory of claim 14, wherein the first and second conductive tracks are made of a first material and wherein the interconnection elements are made of a second material having a poorer electric conductivity than the first material.
